(19) United States
(12) Patent Application Publication
(10) Pub. No.: US 2011/0247678 A1
(43) Pub. Date: Oct. 13, 2011

(54) CONCENTRATED PHOTOVOLTAIC MODULE AND PHOTOVOLTAIC ARRAY MODULE HAVING THE SAME

(76) Inventor: Jong-Hwua Willy FAN, San Jose, CA (US)

(21) Appl. No.: 13/080,218

(22) Filed: Apr. 5, 2011

Related U.S. Application Data
(60) Provisional application No. 61/322,313, filed on Apr. 9, 2010.

(51) Int. Cl. H01L 31/052; H01L 31/0232

(52) U.S. Cl. 136/246; 136/259

(57) ABSTRACT

A concentrated photovoltaic module includes: a base unit including a metal conductor inserted fittingly into an insulating tubular body; a photovoltaic cell disposed in the insulating tubular body and mounted on a top end of the metal conductor; and a hollow light-guiding cover connected sealingly to the insulating tubular body such that the light-guiding cover cooperates with the base unit to define a closed inner space and such that the light-guiding cover guides light into the insulating tubular body of the base unit and onto the photovoltaic cell. The light-guiding cover and the insulating tubular body are made from the same transparent material. A photovoltaic array module including a plurality of the concentrated photovoltaic module is also disclosed.

### CROSS-REFERENCE TO RELATED APPLICATION

This application claims priority of U.S. Provisional Application No. 61/322,313, filed on Apr. 9, 2010.

### BACKGROUND OF THE INVENTION

1. Field of the Invention

The invention relates to a photovoltaic cell, and more particularly to a concentrated photovoltaic module, and a photovoltaic array module having the same.

2. Description of the Related Art

FIGS. 1 to 3 illustrate a conventional photovoltaic array module 1 disclosed in U.S. Pat. No. 6,717,045. The conventional photovoltaic array module 1 includes a plurality of first optical concentrators 11 arranged to form an array, a plurality of second optical concentrators 12 each disposed coaxially below a corresponding first optical concentrator 11, a plurality of third optical concentrators 13 each disposed coaxially at the bottom of a corresponding second optical concentrator 12, and a plurality of multi-junction concentrator solar cells 14 each disposed coaxially below a corresponding third optical concentrator 13.

To perform of solar concentration, each first optical concentrator 11 is a Fresnel lens, each second optical concentrator 12 is a compound parabolic concentrator, and each third optical concentrator 13 is an optical concentrating glass lens. Each solar cell 14 is a tandem GaInP/GaInAs concentrator solar cell. However, the Fresnel lens and the compound parabolic concentrator of the conventional photovoltaic array module 1 are expensive optical components. Therefore, the conventional photovoltaic array module 1 has higher fabrication costs.

Furthermore, because the first, second and third optical concentrators 11, 12, 13 of the conventional photovoltaic array module 1 are made from materials that expand or contract in response to temperature changes, alignment among each first optical concentrator 11, corresponding second and third optical concentrators 12, 13 and the corresponding solar cell 14 may not be attained under various temperature conditions. Similarly, temperature related expansion and contraction of the conventional photovoltaic array module 1 may allow moisture ingress into the package and result in damage to metal components, thereby reducing reliability and service life. Therefore, improvements may be made in the above techniques.

### SUMMARY OF THE INVENTION

Therefore, an object of the present invention is to provide a concentrated photovoltaic module, and a photovoltaic array module having the same that can overcome the aforesaid drawbacks of the prior art.

According to one aspect of the present invention, a concentrated photovoltaic module comprises:

a base unit including an insulating tubular body, and a metal conductor inserted fittingly into the insulating tubular body;

a photovoltaic cell disposed in the insulating tubular body and mounted on a top end of the metal conductor of the base unit; and

a hollow light-guiding cover having a lower open end connected sealingly to the insulating tubular body such that the light-guiding cover cooperates with the base unit to define a closed inner space and such that the light-guiding cover guides light into the insulating tubular body of the base unit and onto the photovoltaic cell.

The light-guiding cover and the insulating tubular body of the base unit are made from the same transparent material.

According to another aspect of the present invention, photovoltaic array module comprises:

amounting frame having a flat top surface and a bottom surface, and formed with a plurality of mounting holes extending from the top surface to the bottom surface and arranged to form an array;

a plurality of concentrated photovoltaic modules mounted respectively in the mounting holes in the mounting frame such that each of said concentrated photovoltaic modules is arranged along a central axis thereof perpendicular to said top surface of said mounting frame, each of the concentrated photovoltaic modules including

a base unit including an insulating tubular body, and a metal conductor inserted fittingly into the insulating tubular body,

a photovoltaic cell disposed in the insulating tubular body and mounted on a top end of the metal conductor of the base unit, and

a hollow light-guiding cover extending through a corresponding one of the mounting holes in the mounting frame, the light-guiding cover having a lower open end connected sealingly to the insulating tubular body such that the light-guiding cover cooperates with the base unit to define a closed inner space and such that the light-guiding cover guides light into the insulating tubular body of the base unit and onto the photovoltaic cell, and an upper end engaged in the corresponding one of the mounting holes in the mounting frame, the light-guiding cover and the insulating tubular body of the base unit being made from the same transparent material; and

an anchoring unit for anchoring the light-guiding covers of the concentrated photovoltaic modules to the mounting frame.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic top view of a conventional photovoltaic array module;

FIG. 2 is a schematic front view of the conventional photovoltaic array module;

FIG. 3 is a fragmentary, enlarged schematic view of the conventional photovoltaic array module;

FIG. 4 is a fragmentary schematic top view showing the preferred embodiment of a concentrated photovoltaic array module;

FIG. 5 is a partly schematic sectional view of the preferred embodiment taken along line V-V in FIG. 4;

FIG. 6 is a fragmentary schematic top view showing a mounting frame of the preferred embodiment;

FIG. 7 is a fragmentary schematic sectional view showing a concentrated photovoltaic module of the preferred embodiment; and

FIG. 8 is a fragmentary schematic sectional view showing another embodiment of the concentrated photovoltaic module.

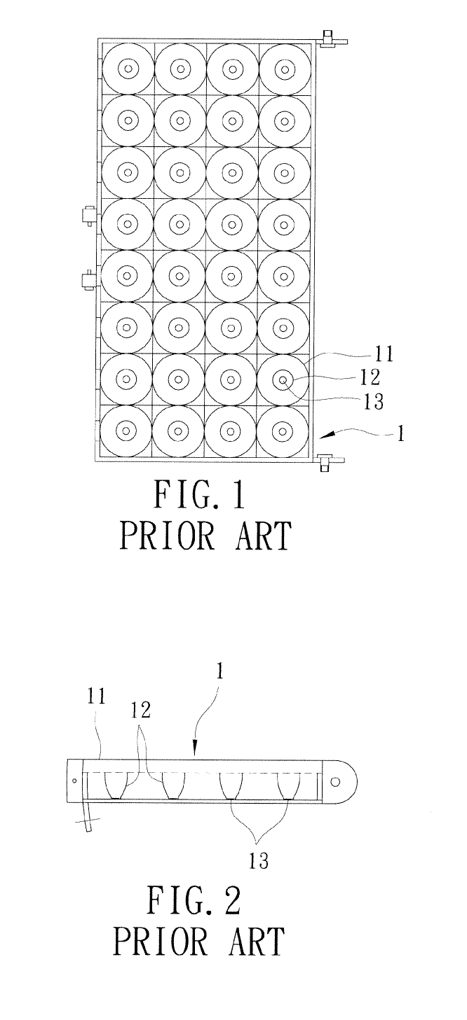

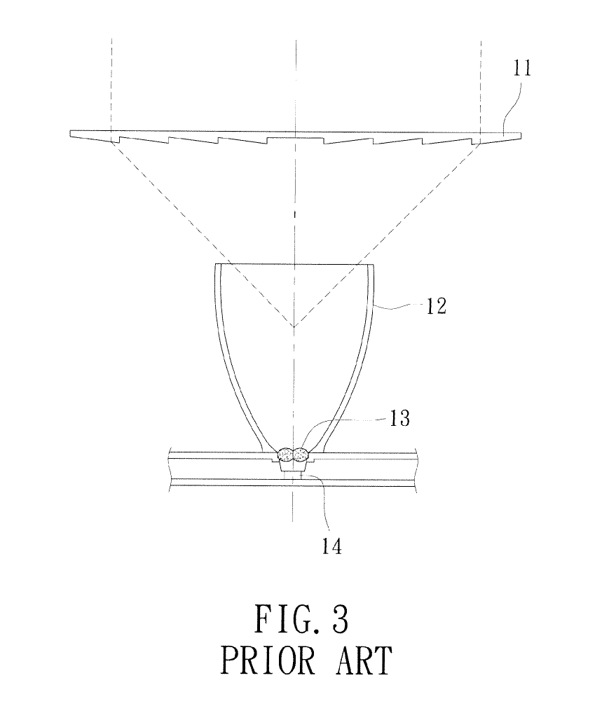

### DETAILED DESCRIPTION OF THE PREFERRED EMBODIMENT

Before the present invention is described in greater detail, it should be noted that like elements are denoted by the same reference numerals throughout the disclosure.

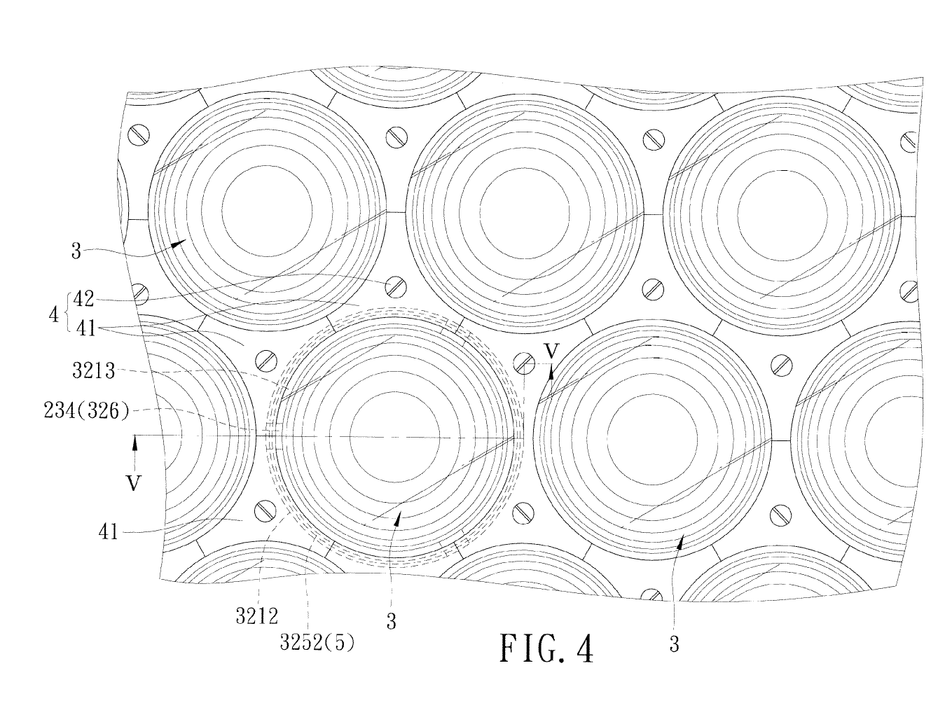

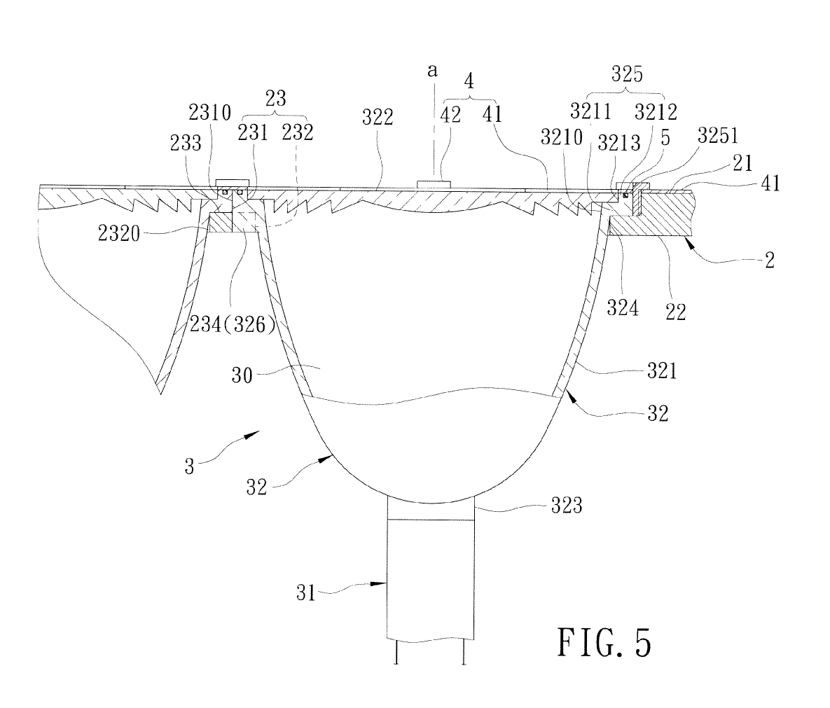

Referring to FIGS. 4 and 5, the preferred embodiment of a photovoltaic array module according to the present invention is shown to include a mounting frame 2, a plurality of concentrated photovoltaic modules 3, and an anchoring unit 4.

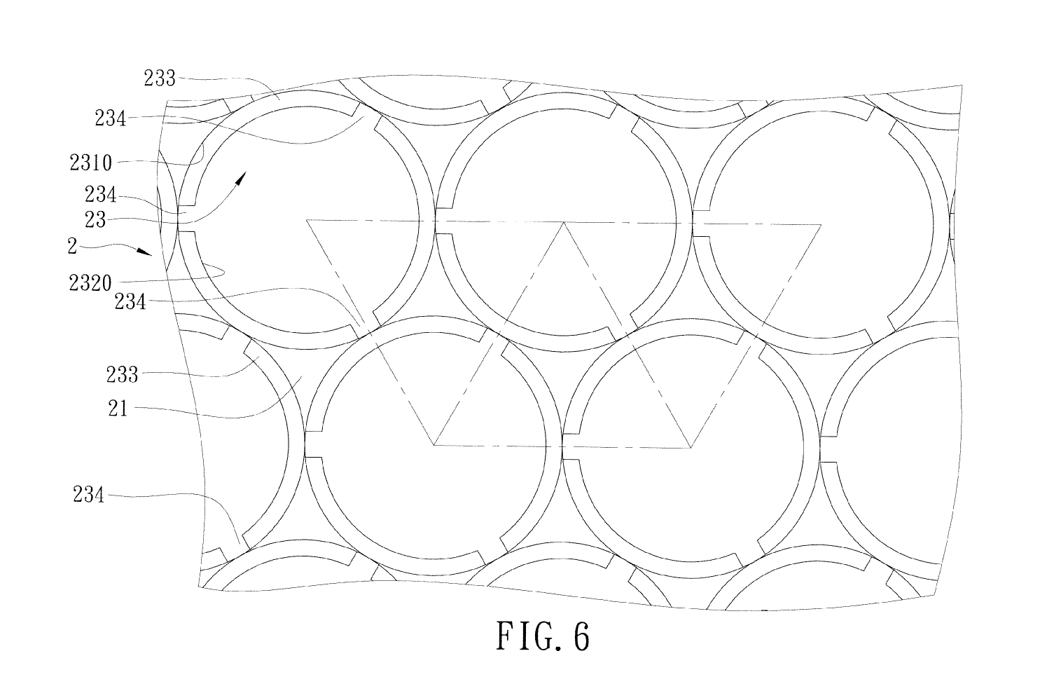

Referring further to FIGS. 5 and 6, the mounting frame 2 is made of steel, and is in the form of a plate body. The mounting frame 2 has a flat top surface 21 and a flat bottom surface 22, and is formed with a plurality of mounting holes 23 extending from the top surface 21 to the bottom surface 22 and arranged to form an equilateral triangular array (see FIG. 6). Each mounting hole 23 has a large-diameter upper hole 231 defined by a first annular wall 2310, a small-diameter lower hole 232 defined by a second annular wall 2320, and a flat annular shoulder surface 233 parallel to the top surface 21, interconnecting the first annular wall 2310 and the second annular wall 2320 and formed with three angularly equidistant positioning grooves 234.

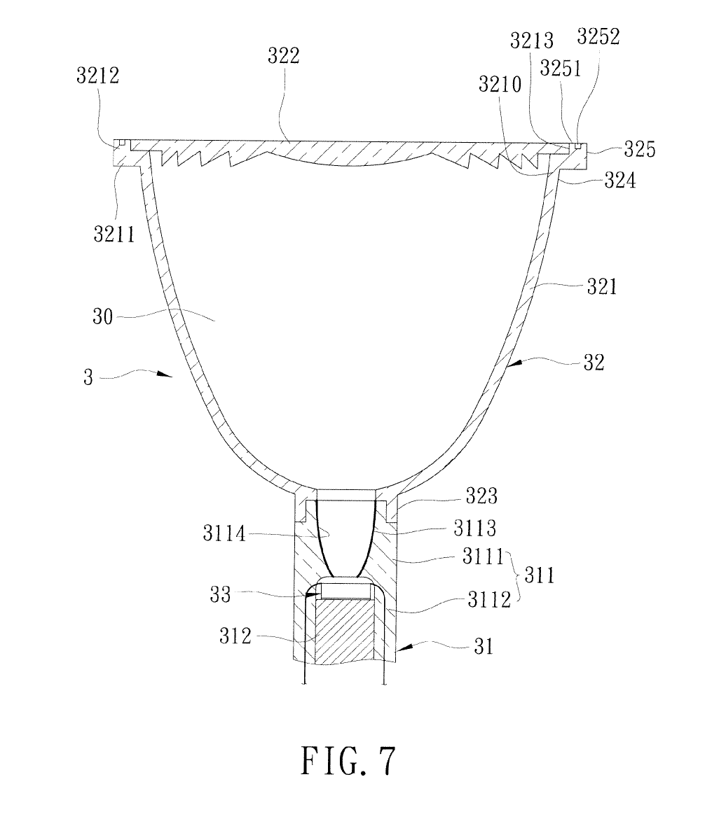

The concentrated photovoltaic modules 3 are mounted respectively in the mounting holes 23 in the mounting frame 2 such that each concentrated photovoltaic module 3 is arranged along a central axis (a) thereof perpendicular to said top surface 21 of said mounting frame 2 (see FIG. 5). Referring further to FIG. 7, each concentrated photovoltaic module 3 includes abase unit 31, a photovoltaic cell 33, and a hollow light-guiding cover 32.

For each concentrated photovoltaic module 3, the base unit 31 includes an insulating tubular body 311 and a metal conductor 312. The insulating tubular body 311 has an upper end portion 3111 and a lower end portion 3112. The upper end portion 3111 has a parabolic-like inner surrounding surface 3113 that is coated with a metal reflective layer 3114. The metal conductor 312, such as a metal rod, is received in and inserted fittingly into the lower end portion 3111 of the insulating tubular body 311. The photovoltaic cell 33 is a multi-junction solar cell. The photovoltaic cell 33 is disposed coaxially in the lower end portion 3112 of the insulating tubular body 311 and is mounted on a atop end of the metal conductor 312 such that the photovoltaic cell 33 has a negative electrode (not shown) electrically contacts the metal conductor 312, and a positive electrode (not shown) adapted to be connected electrically to an external device (not shown) by wires (see FIG. 7). The light-guiding cover 32 extends through a corresponding mounting hole 23 in the mounting frame 2. The light-guiding cover 32 is used to guide light into the insulating tubular body 311 of the base unit 31. It is noted that the light-guiding cover 32 and the insulating tubular body 311 of the base unit 31 are made from the same transparent material, such as a glass material. In addition, preferably, the transparent material, and a metal material made of the metal conductor 312 have the same low thermal expansion coefficient. For example, when the glass material is borosilicate glass having the thermal expansion coefficient of 4.0×10⁻⁶/° K and available from the Corning®3320 fabricated by Corning glass corporation, the metal material can be wolfram (W). In another example, when the glass material is borosilicate glass having the thermal expansion coefficient of 4.6×10⁻⁶/° K and available from the Corning®7052 fabricated by Corning glass corporation, the metal material can be molybdenum (Mo).

The light-guiding cover 32 is mounted coaxially to the base unit 31, and has a lower open end 323 and an upper end 324. The lower open end 323 is connected sealingly to the upper end portion 3111 of the insulating tubular body 311 of the base unit 31 by fritting or sintering the same transparent material filled between the upper end portion 3111 of the insulating tubular body 311 and the lower open end 323. The upper end 324 has a radially and outward extending annular engaging flange 325 that has an outer diameter substantially equal to a diameter of the upper hole portion 231 of the corresponding mounting hole 23 in the mounting frame 2 and that abuts against the annular shoulder surface 233 in the corresponding mounting hole 23 such that the annular engaging flange 325 is retained in the upper hole portion 231 of the corresponding mounting hole 23, thereby engaging the upper end 324 of the light-guiding cover 32 in the corresponding mounting hole 23.

Furthermore, the light-guiding cover 32 further has three angularly equidistant positioning blocks 326 (only one is shown in FIG. 5) that extend downward from a bottom side of the annular engaging flange 325 and that engage respectively the positioning grooves 234 in the annular shoulder surface 233 in the corresponding mounting hole 23 in the mounting frame 2. The annular engaging flange 325 has a top surface 3251 that is coplanar with the top surface 21 of the mounting frame 2 in this embodiment (see FIG. 5) and that is formed with an annular receiving groove 3252 (see FIG. 7).

The light-guiding cover 32 consists of a bowl-like cap body 321 and a circular lens body 322. The cap body 321 has a first open end 3210, and a second open end opposite to the first open end 3210 and serving as the lower open end 323 of the light-guiding cover 32. The first open end 3210 has a diameter larger than that of the second open end. The cap body 321 further has an annular rim flange 3211 extending radially and outward from the first open end 3210, and an annular protrusion 3212 extending upward from a top side of the annular rim flange 3211 and cooperating with the annular rim flange 3211 to define an annular groove 3213. The annular rim flange 3211 and the annular protrusion 3212 constitute the annular engaging flange 325. The lens body 322 has a periphery received in the annular groove 3213 in the first open end 3210 of the cap body 321. The lens body 322 is connected sealingly to the first open end 3210 of the cap body 321 by fritting or sintering the same transparent material filled among the periphery of the lens body 322, the annular rim flange 3211 and the annular protrusion 3212 of the cap body 321 to thereby cover the first open end 3210 of the cap body 321. As such, the light-guiding cover 32 cooperates with the base unit 31 to define a closed inner space 30. Preferably, the closed inner space 30 is a vacuum space.

In this embodiment, the lens body 322 of the light-guiding cover 32 of each concentrated photovoltaic module 3 is in the form of a Fresnel lens that serves as a first optical component. The metal reflective layer 3114 coated on the inner surrounding surface 3113 of the upper end portion 3111 of the insulating tubular body 311 of the base unit 31 of each concentrated photovoltaic module 3 serves as a second optical component. Therefore, for each concentrated photovoltaic module 3, the light-guiding cover 32 guides light into the insulating tubular body 311 of the base unit 31. Then, the light guided by the light-guiding cover 32 is reflected onto the photovoltaic cell 33 by the metal reflective layer 3114.

The anchoring unit 4 is used to anchor the light-guiding covers 32 of the concentrated photovoltaic modules 3 to the mounting frame 2. In this embodiment, as shown in FIG. 4, the anchoring unit 4 includes a plurality of plate bodies 41, and a plurality of fasteners 42. Each plate body 41 is disposed on the top surface 21 of the mounting frame 2, and partially covers the annular protrusions 3212 of the annular engaging flanges 325 of the light-guiding covers 32 of three corresponding concentrated photovoltaic modules 3 adjacent to one another. The annular protrusion 3212 of the annular engaging flange 325 of the light-guiding cover 32 of each concentrated photovoltaic module 3 is fully covered by six corresponding plate bodies 41 such that the lens body 322 of the same is fully exposed. Each fastener 42 extends through a corresponding plate body 41 and into the mounting frame 2 to fasten the corresponding plate body 41 on the top surface 21 of the mounting frame 2. As a result, the concentrated photovoltaic modules 3 are anchored to the mounting frame 2.

The photovoltaic array module further includes a plurality of elastic buffer members 5. In this embodiment, each buffer member 5 is an O-ring, and is received in the annular receiving groove 3252 in the light-guiding cover 32 of a corresponding concentrated photovoltaic module 3, and abuts against six corresponding plate bodies 4 that cover the annular protrusion 3212 of the annular engaging flange 325 of the light-guiding cover of the corresponding concentrated photovoltaic module 3.

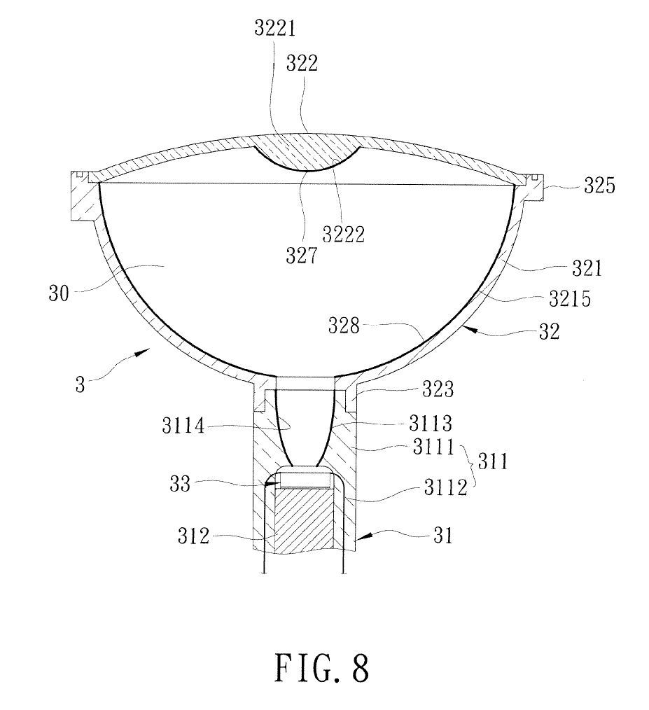

FIG. 8 illustrates another embodiment of the concentrated photovoltaic module 3. In this embodiment, the lens body 322 of the light-guiding cover 32 has a central portion 3221 aligned with the photovoltaic cell 33. The central portion 3221 has a convex bottom surface 3222. The cap body 321 of the light-guiding cover 32 has a hemispheric-like inner surface 3215. The light-guiding cover 32 further includes a first metal reflective layer 327 coated on the bottom surface 3222 of the central portion 3221 of the lens body 322, and a second metal reflective layer 328 coated on the inner surface 3215 of the cap body 321. The first and second metal reflective layers 327, 328 constitute the first optical concentrator. As such, light passing through the lens body 322 is reflected by the second metal reflective layer 328 and by the first metal reflective layer 327 into the tubular body 311 and onto the photovoltaic cell 33. It is noted that the lens body 322, the first metal reflective layer 327, the cap body 321 and the second metal reflective layer 328 cooperatively constitute a structure of a Cassegrain reflector.

In sum, because the light-guiding cover 2 and the tubular body 311 of each concentrated photovoltaic module 3 are made from the same transparent material with a low thermal expansion coefficient, temperature related expansion and contraction can be minimized, thereby ensuring alignment among the light-guiding cover 32, the base unit 31 and the photovoltaic cell 33. Furthermore, because the closed inner space 30 in each concentrated photovoltaic module 3 is a vacuum space, damage to each concentrated photovoltaic module 3 encountered in the prior art can be avoided. Therefore, the photovoltaic array module of the present invention can ensure its performance and has improved reliability.

In addition, for each concentrated photovoltaic module 3, the light-guiding cover 32 has a bulb-like shape and the base unit 31 can be designed as a lamp base. As such, each concentrated photovoltaic module 3 has fewer parts compared to the prior art and can be easily fabricated at relatively low cost using current lighting industry technologies.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A concentrated photovoltaic module comprising:
a base unit including an insulating tubular body, and a metal conductor inserted fittingly into said insulating tubular body;
a photovoltaic cell disposed in said insulating tubular body and mounted on a top end of said metal conductor of said base unit; and
a hollow light-guiding cover having a lower open end connected sealingly to said insulating tubular body such that said light-guiding cover cooperates with said base unit to define a closed inner space and such that said light-guiding cover guides light into said insulating tubular body of said base unit and onto said photovoltaic cell;
wherein said light-guiding cover and said insulating tubular body of said base unit are made from the same transparent material.

2. The concentrated photovoltaic module as claimed in claim 1, wherein said closed inner space is a vacuum space.

3. The concentrated photovoltaic module as claimed in 1, wherein the transparent material includes a glass material.

4. The concentrated photovoltaic module as claimed in claim 1, wherein said light-guiding cover includes:
a bowl-like cap body having a first open end, and a second open end opposite to said first open end and serving as said lower open end, said first open end having a diameter larger than that of said second open end; and
a lens body connected sealingly to and covering said first open end of said cap body.

5. The concentrated photovoltaic module as claimed in claim 4, wherein said cap body has an annular rim flange extending radially and outwardly from said first open end, and an annular protrusion extending upward from a top side of said annular rim flange and cooperating with said annular rim flange to define an annular groove that engages a periphery of said lens body.

6. The concentrated photovoltaic module as claimed in claim 4, wherein said lens body is in the form of a Fresnel lens.

7. The concentrated photovoltaic module as claimed in claim 4, wherein:
said lens body of said light-guiding cover has a central portion aligned with said photovoltaic cell, said central portion having a convex bottom surface;
said cap body of said light-guiding cover has an inner surface;
said light-guiding cover further includes a first metal reflective layer coated on said bottom surface of said central portion of said lens body, and a second metal reflective layer coated on said inner surface of said cap body such that light passing through said lens body is reflected by said second metal reflective layer and by said first metal reflective layer onto said photovoltaic cell; and
said lens body, said first metal reflective layer, said cap body and said second metal reflective layer cooperatively constitute a structure of a Cassegrain reflector.

8. The concentrated photovoltaic module as claimed in claim 1, wherein said insulating tubular body has an upper end portion connected sealingly to said lower open end of said light-guiding cover, and a lower end portion receiving said metal conductor and said photovoltaic cell therein, said upper end portion having a parabolic-like inner surrounding surface coated with a metal reflective layer such that the light guided into said insulating tubular body of said base unit by said light-guiding cover is reflected onto said photovoltaic cell by said metal reflective layer.

9. A photovoltaic array module comprising:
amounting frame having a flat top surface and a bottom surface, and formed with a plurality of mounting holes extending from said top surface to said bottom surface and arranged to form an array;
a plurality of concentrated photovoltaic modules mounted respectively in said mounting holes in said mounting frame such that each of said concentrated photovoltaic modules is arranged along a central axis thereof perpendicular to said top surface of said mounting frame, each of said concentrated photovoltaic modules including
abase unit including an insulating tubular body, and a metal conductor inserted fittingly into said insulating tubular body,
a photovoltaic cell disposed in said insulating tubular body and mounted on a top end of said metal conductor of said base unit, and
a hollow light-guiding cover extending through a corresponding one of said mounting holes in said mounting frame, said light-guiding cover having a lower open end connected sealingly to said insulating tubular body such that said light-guiding cover cooperates with said base unit to define a closed inner space and such that said light-guiding cover guides light into said insulating tubular body of said base unit and onto said photovoltaic cell, and an upper end engaged in the corresponding one of said mounting holes in said mounting frame, said light-guiding cover and said insulating tubular body of said base unit being made from the same transparent material; and
an anchoring unit for anchoring said light-guiding covers of said concentrated photovoltaic modules to said mounting frame.

10. The photovoltaic array module as claimed in claim 9, wherein:
each of said mounting holes in said mounting frame has a large-diameter upper hole portion defined by a first annular wall, a small-diameter lower hole portion defined by a second annular wall, and a flat annular shoulder surface parallel to said top surface of said mounting frame and interconnecting said first annular wall and said second annular wall; and
said upper end of said light-guiding cover of each of said concentrated photovoltaic modules has a radially and outward extending annular engaging flange that has an outer diameter substantially equal to a diameter of said upper hole portion of the corresponding one of said mounting holes in said mounting frame and that abuts against said annular shoulder surface in the corresponding one of said mounting holes in said mounting frame such that said annular engaging flange is retained in said upper hole portion of the corresponding one of said mounting holes, thereby engaging said upper end of said light-guiding cover of each of said concentrated photovoltaic modules in the corresponding one of said mounting holes in said mounting frame.

11. The photovoltaic array module as claimed in claim 10, wherein:
said annular shoulder surface in each of said mounting holes in said mounting frame is formed with at least one positioning groove; and
said light-guiding cover of each of said concentrated photovoltaic modules further has at least one positioning block extending downward from a bottom side of said annular engaging flange and engaging respectively said positioning grooves in said annular shoulder surface in the corresponding one of said mounting holes in said mounting frame.

12. The photovoltaic array module as claimed in claim 10, wherein said anchoring unit includes:
a plurality of plate bodies each disposed on said top surface of said mounting frame and partially covering said annular engaging flanges of said light-guiding covers of corresponding ones of said concentrated photovoltaic modules adjacent to one another, said annular engaging flange of said light-guiding cover of each of said concentrated photovoltaic modules being fully covered by corresponding ones of said plate bodies; and
a plurality of fasteners each extending through a corresponding one of said plate bodies and into said mounting frame to fasten the corresponding one of said plate bodies on said top surface of said mounting frame.

13. The photovoltaic array module as claimed in claim 12, wherein said annular engaging flange of said light-guiding cover of each of said concentrated photovoltaic modules has a top surface that is not higher than said top surface of said mounting frame and that is formed with an annular receiving groove;
said photovoltaic array module further comprising a plurality of elastic buffer members each received in said annular receiving groove in said light-guiding cover of a corresponding one of said concentrated photovoltaic modules and abutting against corresponding ones of said plate bodies that cover the corresponding one of said concentrated photovoltaic modules.

14. The photovoltaic array module as claimed in claim 13, wherein each of said buffer members includes an O-ring.

15. The photovoltaic array module as claimed in claim 10, wherein:
said light-guiding cover of each of said concentrated photovoltaic modules includes
a bowl-like cap body having a first open end, and a second open end opposite to said first open end and serving as said lower open end, said first open end having a diameter larger than that of said second open end, and
a lens body connected sealingly to and covering said first open end of said cap body; and
said cap body of said light-guiding cover of each of said concentrated photovoltaic modules further has an annular rim flange extending radially and outward from said first open end, and an annular protrusion extending upward from a top side of said annular rim flange and cooperating with said annular rim flange to define an annular groove that engages a periphery of said lens body, said annular rim flange and said annular protrusion constituting said annular engaging flange.

16. The photovoltaic array module as claimed in claim 15, wherein said lens body of said light-guiding cover of each of said concentrated photovoltaic modules is in the form of a Fresnel lens.

17. The photovoltaic module as claimed in claim 15, wherein, for each of said concentrated photovoltaic modules:
said lens body of said light-guiding cover has a central portion aligned with said photovoltaic cell, said central portion having a convex bottom surface;
said cap body of said light-guiding cover has an inner surface;
said light-guiding cover further includes a first metal reflective layer coated on said bottom surface of said central portion of said lens body, and a second metal reflective layer coated on said inner surface of said cap body such that light passing through said lens body is reflected by said second metal reflective layer and by said first metal reflective layer onto said photovoltaic cell; and
said lens body, said first metal reflective layer, said cap body and said second metal reflective layer cooperatively constitute a structure of a Cassegrain reflector.

18. The photovoltaic module as claimed in claim 9, wherein said insulating tubular body of said base unit of each of said concentrated photovoltaic modules has an upper end portion connected sealingly to said lower open end of said light-guiding cover, and a lower end portion receiving said metal conductor and said photovoltaic cell therein, said upper end portion having a parabolic-like inner surrounding surface coated with a metal reflective layer such that the light guided into said insulating tubular body of said base unit by said light-guiding cover is reflected onto said photovoltaic cell by said metal reflective layer.

19. The photovoltaic array module as claimed in claim 9, wherein said closed inner space in each of said concentrated photovoltaic modules is a vacuum space.

20. The photovoltaic array module as claimed in claim 9, wherein the transparent material includes a glass material.
